(19) United States
(12) Patent Application Publication
(10) Pub. No.: US 2025/0006730 A1
(43) Pub. Date: Jan. 2, 2025

(54) STACKED TRANSISTORS WITH DIELECTRIC INSULATOR LAYERS

(71) Applicant: International Business Machines Corporation, Armonk, NY (US)

(72) Inventors: Ruilong Xie, Niskayuna, NY (US); Julien Frougier, Albany, NY (US); Shay Reboh, Guilderland, NY (US); Tenko Yamashita, Schenectady, NY (US)

(21) Appl. No.: 18/342,090

(22) Filed: Jun. 27, 2023

(51) Int. Cl. H01L 27/088; H01L 29/06; H01L 29/423; H01L 29/775

(52) U.S. Cl. CPC H01L 27/088; H01L 29/0673; H01L 29/42392; H01L 29/775

(57) ABSTRACT

A semiconductor structure includes a first stacked device having a first field-effect transistor containing one or more first nanosheet layers, a second field-effect transistor containing one or more second nanosheet layers; and a first dielectric insulator layer positioned between the first field-effect transistor and the second field-effect transistor, the first dielectric insulator layer having a first width. The semiconductor structure further includes a second stacked device adjacent the first stacked device. The second stacked device having a third field-effect transistor containing one or more third nanosheet layers, a fourth field-effect transistor containing one or more fourth nanosheet layers, and a second dielectric insulator layer positioned between the third field-effect transistor and the fourth field-effect transistor. The second dielectric insulator layer has a second width less than the first width of the first dielectric insulator layer.

### BACKGROUND

A field-effect transistor (FET) is a transistor having a source, a gate, and a drain, the operation of which depends on the flow of carriers (electrons or holes) along a channel that runs between the source and drain. Current through the channel between the source and drain may be controlled by a transverse electric field under the gate. FETs are widely used for switching, amplification, filtering, and other tasks.

### SUMMARY

Illustrative embodiments of the present disclosure include techniques for use in semiconductor manufacture. In an illustrative embodiment, a semiconductor structure comprises a first stacked device comprising a first field-effect transistor comprising one or more first nanosheet layers, a second field-effect transistor vertically stacked above the first field-effect transistor, the second field-effect transistor comprising one or more second nanosheet layers, and a first dielectric insulator layer positioned between the first field-effect transistor and the second field-effect transistor, the first dielectric insulator layer having a first width. The semiconductor structure further comprises a second stacked device adjacent the first stacked device. The second stacked device comprises a third field-effect transistor comprising one or more third nanosheet layers, a fourth field-effect transistor vertically stacked above the third field-effect transistor, the fourth field-effect transistor comprising one or more fourth nanosheet layers, and a second dielectric insulator layer positioned between the third field-effect transistor and the fourth field-effect transistor. The second dielectric insulator layer has a second width less than the first width of the first dielectric insulator layer.

The semiconductor structure of the illustrative embodiment advantageously allows for forming a first dielectric insulator layer of a first stacked device having a different width than a second dielectric insulator layer of a second stacked device adjacent the first stacked device resulting in both shared gate integration and independent gate devices.

In one or more additional illustrative embodiments, as may be combined with the preceding paragraphs, the first width of the first dielectric insulator layer is equal to a third width of the one or more second nanosheet layers, and the second width of the second dielectric insulator layer is equal to a fourth width of the one or more third nanosheet layers.

In one or more additional illustrative embodiments, as may be combined with the preceding paragraphs, the semiconductor structure further comprises a third dielectric insulator layer disposed on a bottom surface of the first stacked device and a fourth dielectric insulator layer disposed on a bottom surface of the second stacked device.

In one or more additional illustrative embodiments, as may be combined with the preceding paragraphs, the first stacked device and the second stacked device are separated by an isolation dielectric pillar.

In one or more additional illustrative embodiments, as may be combined with the preceding paragraphs, the first field-effect transistor further comprises a first gate structure and the second field-effect transistor further comprise a second gate structure separated from the first gate structure by the first dielectric insulator layer.

In one or more additional illustrative embodiments, as may be combined with the preceding paragraphs, the semiconductor structure further comprises a first frontside gate contact connected to the first gate structure and a frontside back-end-of-the-line layer.

In one or more additional illustrative embodiments, as may be combined with the preceding paragraphs, the semiconductor structure further comprises a backside gate contact connected to the second gate structure and a backside back-end-of-the-line layer.

In one or more additional illustrative embodiments, as may be combined with the preceding paragraphs, the second stacked device further comprises a third gate structure disposed over the third field-effect transistor and the fourth field-effect transistor.

In one or more additional illustrative embodiments, as may be combined with the preceding paragraphs, the semiconductor structure further comprises a second frontside gate contact connected to the third gate structure and a frontside back-end-of-the-line layer.

In another illustrative embodiment, a semiconductor structure comprises a first stacked device structure comprising a first field-effect transistor disposed comprising a first source/drain region, and a second field-effect transistor vertically stacked above the first field-effect transistor, the second field-effect transistor comprising a second source/drain region. The first stacked device further comprises a frontside source/drain contact disposed on a first portion of a sidewall and a top surface of the second source/drain region, and a first metal via connected to the frontside source/drain contact and to a first backside power line. The semiconductor structure further comprises a second stacked device structure adjacent the first stacked device structure. The second stacked device structure comprises a third field-effect transistor comprising a third source/drain region, and a fourth field-effect transistor vertically stacked above the third field-effect transistor, the fourth field-effect transistor comprising a fourth source/drain region. The second stacked device structure further comprises a first backside source/drain contact disposed on a second portion of a sidewall and a bottom surface of the third source/drain region, and a second metal is via connected on to the first backside source/drain contact and to a back-end-of-the-line layer.

The semiconductor structure of the illustrative embodiment advantageously allows for forming a first dielectric insulator layer of a first stacked device having a different width than a second dielectric insulator layer of a second stacked device adjacent the first stacked device resulting in both shared gate integration and independent gate devices.

In one or more additional illustrative embodiments, as may be combined with the preceding paragraphs, the third gate structure is a shared gate structure between the third stacked device and the fourth stacked device.

In one or more additional illustrative embodiments, as may be combined with the preceding paragraphs, the semiconductor structure further comprises a first frontside gate contact connected to the third gate structure and a frontside back-end-of-the-line layer.

In one or more additional illustrative embodiments, as may be combined with the preceding paragraphs, the semiconductor structure further comprises a second frontside gate contact connected to the first gate structure and the frontside back-end-of-the-line layer.

In one or more additional illustrative embodiments, as may be combined with the preceding paragraphs, the semiconductor structure further comprises a backside gate contact connected to the second gate structure and a backside back-end-of-the-line layer.

In one or more additional illustrative embodiments, as may be combined with the preceding paragraphs, the first dielectric insulator layer has a first width and the second dielectric insulator layer has a second width less than the first width of the first dielectric insulator layer.

In one or more additional illustrative embodiments, as may be combined with the preceding paragraphs, the first stacked device and the second stacked device are separated by an isolation dielectric pillar.

Another exemplary embodiment comprises an integrated circuit comprising one or more semiconductor structures. At least one of the one or more semiconductor structures is a semiconductor structure according to one or more of the foregoing embodiments.

These and other exemplary embodiments will be described in or become apparent from the following detailed description of exemplary embodiments, which is to be read in connection with the accompanying drawings.

### BRIEF DESCRIPTION OF THE DRAWINGS

Exemplary embodiments will be described below in more detail, with reference to the accompanying drawings, of which:

FIG. 1A is a top view illustrating a semiconductor structure for use at a first-intermediate fabrication stage, according to an illustrative embodiment.

FIG. 1B is a cross-sectional view of the semiconductor structure taken along the X-X axis of FIG. 1A at the first-intermediate fabrication stage, according to an illustrative embodiment.

FIG. 1C is a cross-sectional view of the semiconductor structure taken along the Y1-Y1 axis of FIG. 1A at the first-intermediate fabrication stage, according to an illustrative embodiment.

FIG. 1D is a cross-sectional view of the semiconductor structure taken along the Y2-Y2 axis of FIG. 1A at the first-intermediate fabrication stage, according to an illustrative embodiment.

FIG. 2A is a cross-sectional view of the semiconductor structure taken along the X-X axis of FIG. 1A at a second-intermediate fabrication stage, according to an illustrative embodiment.

FIG. 2B is a cross-sectional view of the semiconductor structure taken along the Y1-Y1 axis of FIG. 1A at the second-intermediate fabrication stage, according to an illustrative embodiment.

FIG. 2C is a cross-sectional view of the semiconductor structure taken along the Y2-Y2 axis of FIG. 1A at the second-intermediate fabrication stage, according to an illustrative embodiment.

FIG. 3A is a cross-sectional view illustrating the semiconductor structure taken along the X-X axis of FIG. 1A at a third-intermediate fabrication stage, according to an illustrative embodiment.

FIG. 3B is a cross-sectional view illustrating the semiconductor structure taken along the Y1-Y1 axis of FIG. 1A at the third-intermediate fabrication stage, according to an illustrative embodiment.

FIG. 3C is a cross-sectional view illustrating the semiconductor structure taken along the Y2-Y2 axis of FIG. 1A at the third-intermediate fabrication stage, according to an illustrative embodiment.

FIG. 4A is a cross-sectional view illustrating the semiconductor structure taken along the X-X axis of FIG. 1A at a fourth-intermediate fabrication stage, according to an illustrative embodiment.

FIG. 4B is a cross-sectional view illustrating the semiconductor structure taken along the Y1-Y1 axis of FIG. 1A at the fourth-intermediate fabrication stage, according to an illustrative embodiment.

FIG. 4C is a cross-sectional view illustrating the semiconductor structure taken along the Y2-Y2 axis of FIG. 1A at the fourth-intermediate fabrication stage, according to an illustrative embodiment.

FIG. 5A is a cross-sectional view illustrating the semiconductor structure taken along the X-X axis of FIG. 1A at a fifth-intermediate fabrication stage, according to an illustrative embodiment.

FIG. 5B is a cross-sectional view illustrating the semiconductor structure taken along the Y1-Y1 axis of FIG. 1A at the fifth-intermediate fabrication stage, according to an illustrative embodiment.

FIG. 5C is a cross-sectional view illustrating the semiconductor structure taken along the Y2-Y2 axis of FIG. 1A at the fifth-intermediate fabrication stage, according to an illustrative embodiment.

FIG. 6A is a cross-sectional view of the semiconductor structure taken along the X-X axis of FIG. 1A at a sixth-intermediate fabrication stage, according to an illustrative embodiment.

FIG. 6B is a cross-sectional view of the semiconductor structure taken along the Y1-Y1 axis of FIG. 1A at the sixth-intermediate fabrication stage, according to an illustrative embodiment.

FIG. 6C is a cross-sectional view of the semiconductor structure taken along the Y2-Y2 axis of FIG. 1A at the sixth-intermediate fabrication stage, according to an illustrative embodiment.

FIG. 7A is a cross-sectional view illustrating the semiconductor structure taken along the X-X axis of FIG. 1A at a seventh-intermediate fabrication stage, according to an illustrative embodiment.

FIG. 7B is a cross-sectional view illustrating the semiconductor structure taken along the Y1-Y1 axis of FIG. 1A at the seventh-intermediate fabrication stage, according to an illustrative embodiment.

FIG. 7C is a cross-sectional view illustrating the semiconductor structure taken along the Y2-Y2 axis of FIG. 1A at the seventh-intermediate fabrication stage, according to an illustrative embodiment.

FIG. 8A is a cross-sectional view of the semiconductor structure taken along the X-X axis of FIG. 1A at an eighth-intermediate fabrication stage, according to an illustrative embodiment.

FIG. 8B is a cross-sectional view of the semiconductor structure taken along the Y1-Y1 axis of FIG. 1A at the eighth-intermediate fabrication stage, according to an illustrative embodiment.

FIG. 8C is a cross-sectional view of the semiconductor structure taken along the Y2-Y2 axis of FIG. 1A at the eighth-intermediate fabrication stage, according to an illustrative embodiment.

FIG. 9A is a cross-sectional view illustrating the semiconductor structure taken along the X-X axis of FIG. 1A at a ninth-intermediate fabrication stage, according to an illustrative embodiment.

FIG. 9B is a cross-sectional view illustrating the semiconductor structure taken along the Y1-Y1 axis of FIG. 1A at the ninth-intermediate fabrication stage, according to an illustrative embodiment.

FIG. 9C is a cross-sectional view illustrating the semiconductor structure taken along the Y2-Y2 axis of FIG. 1A at the ninth-intermediate fabrication stage, according to an illustrative embodiment.

FIG. 10A is a cross-sectional view illustrating the semiconductor structure taken along the X-X axis of FIG. 1A at a tenth-intermediate fabrication stage, according to an illustrative embodiment.

FIG. 10B is a cross-sectional view illustrating the semiconductor structure taken along the Y1-Y1 axis of FIG. 1A at the tenth-intermediate fabrication stage, according to an illustrative embodiment.

FIG. 10C is a cross-sectional view illustrating the semiconductor structure taken along the Y2-Y2 axis of FIG. 1A at the tenth-intermediate fabrication stage, according to an illustrative embodiment.

FIG. 11A is a cross-sectional view illustrating the semiconductor structure taken along the X-X axis of FIG. 1A at an eleventh-intermediate fabrication stage, according to an illustrative embodiment.

FIG. 11B is a cross-sectional view illustrating the semiconductor structure taken along the Y1-Y1 axis of FIG. 1A at the eleventh-intermediate fabrication stage, according to an illustrative embodiment.

FIG. 11C is a cross-sectional view illustrating the semiconductor structure taken along the Y2-Y2 axis of FIG. 1A at the eleventh-intermediate fabrication stage, according to an illustrative embodiment.

FIG. 12A is a cross-sectional view illustrating the semiconductor structure taken along the X-X axis of FIG. 1A at a twelfth-intermediate fabrication stage, according to an illustrative embodiment.

FIG. 12B is a cross-sectional view illustrating the semiconductor structure taken along the Y1-Y1 axis of FIG. 1A at the twelfth-intermediate fabrication stage, according to an illustrative embodiment.

FIG. 12C is a cross-sectional view illustrating the semiconductor structure taken along the Y2-Y2 axis of FIG. 1A at the twelfth-intermediate fabrication stage, according to an illustrative embodiment.

FIG. 13A is a cross-sectional view illustrating the semiconductor structure taken along the X-X axis of FIG. 1A at a thirteenth-intermediate fabrication stage, according to an illustrative embodiment.

FIG. 13B is a cross-sectional view illustrating the semiconductor structure taken along the Y1-Y1 axis of FIG. 1A at the thirteenth-intermediate fabrication stage, according to an illustrative embodiment.

FIG. 13C is a cross-sectional view illustrating the semiconductor structure taken along the Y2-Y2 axis of FIG. 1A at the thirteenth-intermediate fabrication stage, according to an illustrative embodiment.

FIG. 14A is a cross-sectional view illustrating the semiconductor structure taken along the X-X axis of FIG. 1A at a fourteenth-intermediate fabrication stage, according to an illustrative embodiment.

FIG. 14B is a cross-sectional view illustrating the semiconductor structure taken along the Y1-Y1 axis of FIG. 1A at the fourteenth-intermediate fabrication stage, according to an illustrative embodiment.

FIG. 14C is a cross-sectional view illustrating the semiconductor structure taken along the Y2-Y2 axis of FIG. 1A at the fourteenth-intermediate fabrication stage, according to an illustrative embodiment.

FIG. 15A is a cross-sectional view illustrating the semiconductor structure taken along the X-X axis of FIG. 1A at a fifteenth-intermediate fabrication stage, according to an illustrative embodiment.

FIG. 15B is a cross-sectional view illustrating the semiconductor structure taken along the Y1-Y1 axis of FIG. 1A at the fifteenth-intermediate fabrication stage, according to an illustrative embodiment.

FIG. 15C is a cross-sectional view illustrating the semiconductor structure taken along the Y2-Y2 axis of FIG. 1A at the fifteenth-intermediate fabrication stage, according to an illustrative embodiment.

FIG. 16A is a cross-sectional view illustrating the semiconductor structure taken along the X-X axis of FIG. 1A at a sixteenth-intermediate fabrication stage, according to an illustrative embodiment.

FIG. 16B is a cross-sectional view illustrating the semiconductor structure taken along the Y1-Y1 axis of FIG. 1A at the sixteenth-intermediate fabrication stage, according to an illustrative embodiment.

FIG. 16C is a cross-sectional view illustrating the semiconductor structure taken along the Y2-Y2 axis of FIG. 1A at the sixteenth-intermediate fabrication stage, according to an illustrative embodiment.

FIG. 17A is a cross-sectional view illustrating the semiconductor structure taken along the X-X axis of FIG. 1A at a seventeenth-intermediate fabrication stage, according to an illustrative embodiment.

FIG. 17B is a cross-sectional view illustrating the semiconductor structure taken along the Y1-Y1 axis of FIG. 1A at the seventeenth-intermediate fabrication stage, according to an illustrative embodiment.

FIG. 17C is a cross-sectional view illustrating the semiconductor structure taken along the Y2-Y2 axis of FIG. 1A at the seventeenth-intermediate fabrication stage, according to an illustrative embodiment.

### DETAILED DESCRIPTION

Illustrative embodiments of the invention may be described herein in the context of illustrative methods for forming a first dielectric insulator layer of a first stacked device having a different width than a second dielectric insulator layer of a second stacked device adjacent the first stacked device resulting in both shared gate integration and independent gate devices, along with illustrative apparatus, structures and devices formed using such methods. However, it is to be understood that embodiments of the invention are not limited to the illustrative methods, apparatus, structures and devices but instead are more broadly applicable to other suitable methods, apparatus, structures and devices.

It is to be understood that the various layers, structures, and regions shown in the accompanying drawings are schematic illustrations that are not drawn to scale. In addition, for ease of explanation, one or more layers, structures, and regions of a type commonly used to form semiconductor devices or structures may not be explicitly shown in a given drawing. This does not imply that any layers, structures, and regions not explicitly shown are omitted from the actual semiconductor structures.

Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description. It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present, such as 1% or less than the stated amount.

Reference in the specification to “one embodiment” or “an embodiment” of the present principles, as well as other variations thereof, means that a particular feature, structure, characteristic, and so forth described in connection with the embodiment is included in at least one embodiment of the present principles. Thus, the appearances of the phrase “in one embodiment” or “in an embodiment”, as well any other variations, appearing in various places throughout the specification are not necessarily all referring to the same embodiment. The term “positioned on” means that a first element, such as a first structure, is present on a second element, such as a second structure, wherein intervening elements, such as an interface structure, e.g., interface layer, may be present between the first element and the second element. The term “direct contact” means that a first element, such as a first structure, and a second element, such as a second structure, are connected without any intermediary conducting, insulating or semiconductor layers at the interface of the two elements.

It will be understood that, although the terms first, second, etc. may be used herein to describe various elements, these elements should not be limited by these terms. These terms are only used to distinguish one element from another element. Thus, a first element discussed below could be termed a second element without departing from the scope of the present concept.

As used herein, “height” refers to a vertical size of an element (e.g., a layer, trench, hole, opening, etc.) in the cross-sectional views measured from a bottom surface to a top surface of the element, and/or measured with respect to a surface on which the element is located. Conversely, a “depth” refers to a vertical size of an element (e.g., a layer, trench, hole, opening, etc.) in the cross-sectional views measured from a top surface to a bottom surface of the element. Terms such as “thick”, “thickness”, “thin” or derivatives thereof may be used in place of “height” where indicated.

As used herein, “width” or “length” refers to a size of an element (e.g., a layer, trench, hole, opening, etc.) in the drawings measured from a side surface to an opposite surface of the element. Terms such as “thick”, “thickness”, “thin” or derivatives thereof may be used in place of “width” or “length” where indicated.

In the IC chip fabrication industry, there are three sections referred to in a typical IC chip build: front-end-of-line (FEOL), back-end-of-line (BEOL), and the section that connects those two together, the middle-of-line (MOL). The FEOL is made up of the semiconductor devices, e.g., transistors, the BEOL is made up of interconnects and wiring, and the MOL is an interconnect between the FEOL and BEOL that includes material to prevent the diffusion of BEOL metals to FEOL devices. Accordingly, illustrative embodiments described herein may be directed to BEOL semiconductor processing and structures. BEOL is the second portion of IC fabrication where the individual devices (e.g., transistors, capacitors, resistors, etc.) become interconnected with wiring on the wafer, e.g., the metallization layer or layers. BEOL includes contacts, insulating layers (dielectrics), metal levels, and bonding sites for chip-to-package connections. In the BEOL, part of the fabrication stage contacts (pads), interconnect wires, vias and dielectric structures are formed. For modern IC processes, more than 10 metal layers may be added in the BEOL.

Embodiments described below may be applicable to FEOL processing and structures, BEOL processing and structures, or both FEOL and BEOL processing and structures. In particular, although an exemplary processing scheme may be illustrated using a FEOL processing scenario, such approaches may also be applicable to BEOL processing. Likewise, although an exemplary processing scheme may be illustrated using a BEOL processing scenario, such approaches may also be applicable to FEOL processing.

Present stacked FETs utilize a dielectric insulator layer of a uniform width between the transistors. Thus, present stacked FETS do not allow for both shared gate integration and independent gate devices. There is a need therefore to form stacked FETs without the above drawbacks. Accordingly, non-limiting illustrative embodiments described herein overcome the drawbacks discussed above by forming a first dielectric insulator layer of a first stacked device having a different width than a second dielectric insulator layer of a second stacked device adjacent the first stacked device to allow for both shared gate integration and independent gate devices.

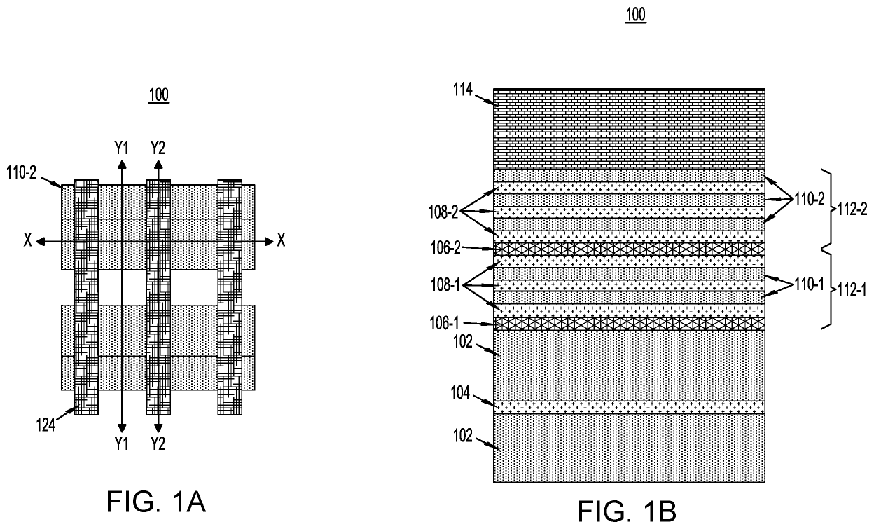

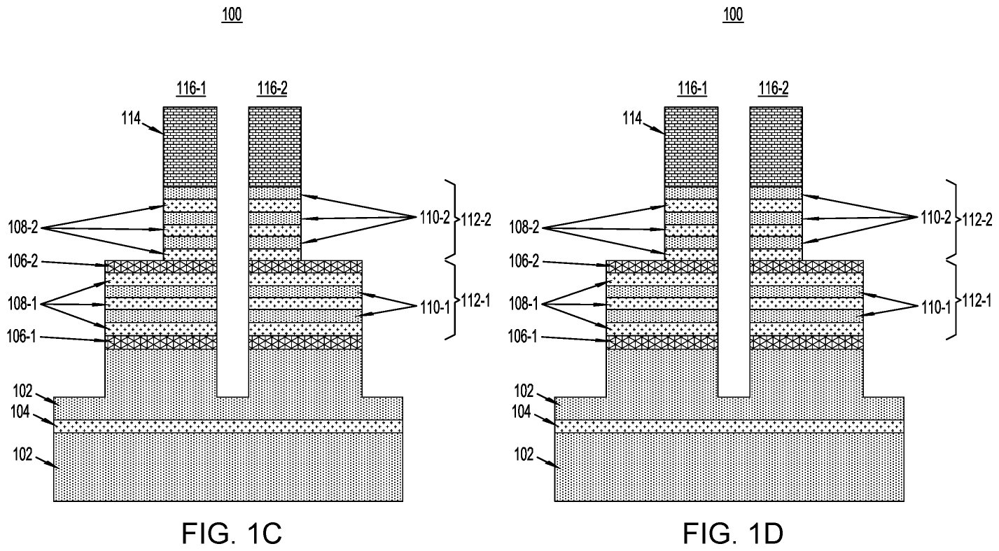

Referring now to FIG. 1A-17C, FIG. 1A shows a top-down view of a semiconductor structure 100. A first side cross-sectional view of FIG. 1B is taken along the line X-X in the top-down view of FIG. 1A, a second side cross-sectional view of FIG. 1C is taken along the line Y1-Y1 in the top-down view of FIG. 1A and a third side cross-sectional view of FIG. 1D is taken along the line Y2-Y2 in the top-down view of FIG. 1A.

Semiconductor structure 100 shows substrate 102. Substrate 102 may be formed of any suitable semiconductor structure, including various silicon-containing materials including but not limited to silicon (Si), silicon germanium (SiGe), silicon germanium carbide (SiGeC), silicon carbide (SiC) and multi-layers thereof. Although silicon is the predominantly used semiconductor material in wafer fabrication, alternative semiconductor materials can be employed as additional layers, such as, but not limited to, germanium (Ge), gallium arsenide (GaAs), gallium nitride (GaN), SiGe, cadmium telluride (CdTe), zinc selenide (ZnSe), etc. In one illustrative embodiment, substrate 102 is silicon.

An etch stop layer 104 is formed in the substrate 102. The etch stop layer 104 may comprise a buried oxide (BOX) layer or silicon germanium (SiGe), or another suitable material such as a III-V semiconductor epitaxial layer.

Nanosheet stacks 116-1 and 116-2 are formed over the substrate 102, each containing nanosheet devices 112-1 and 112-2. Nanosheet devices 112-1 and 112-2 include sacrificial layers 106-1 and 106-2 (collectively, sacrificial layers 106), sacrificial layers 108-1 and 108-2 (collectively, sacrificial layers 108) and nanosheet channel layers 110-1 and 110-2 (collectively, nanosheet channel layers 110).

The sacrificial layers 106 and sacrificial layers 108 are illustratively formed of different sacrificial materials, such that they may be etched or otherwise removed selective to one another. In some embodiments, both the sacrificial layers 106 and sacrificial layers 108 are formed of SiGe, but with different percentages of Ge. For example, the sacrificial layers 106 may have a relatively higher percentage of Ge (e.g., 55% Ge), and the sacrificial layers 108 may have a relatively lower percentage of Ge (e.g., 25% Ge). Other combinations of different sacrificial materials may be used in other embodiments.

In non-limiting illustrative embodiments, nanosheet channel layers 110-1 are of a first width and nanosheet channel layers 110-2 are of a second width less than the first width (see FIGS. 1C and 1D).

The nanosheet channel layers 110 may be formed of Si or another suitable material (e.g., a material similar to that used for the substrate 102).

Nanosheet stacks 116-1 and 116-2 are formed by depositing hard mask (HM) layer 114, followed by lithographic and etching processing. HM layer 114 can be composed of silicon nitride (SiN), a multi-layer of SiN and SiO₂, or another suitable material.

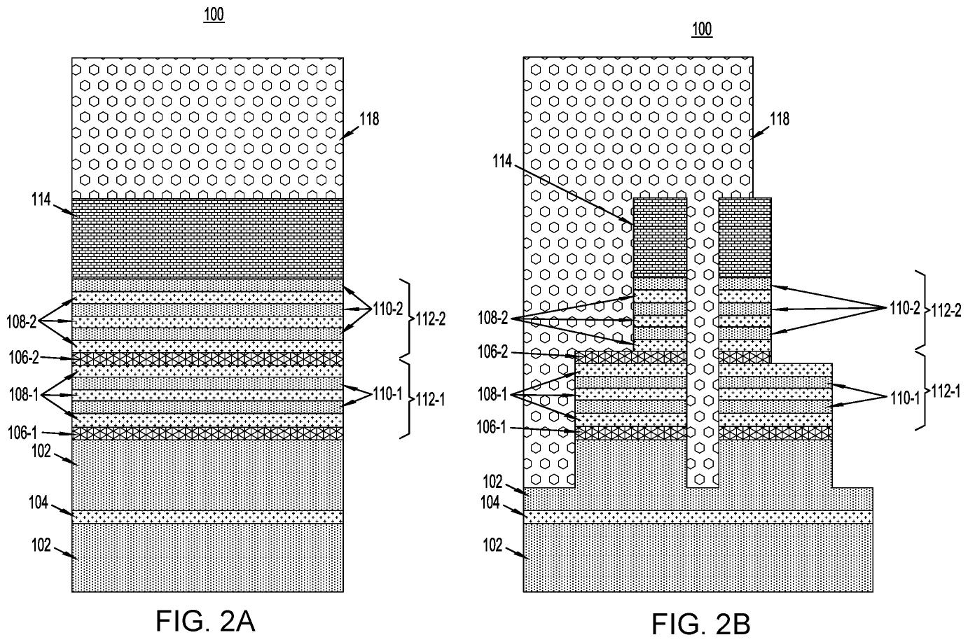

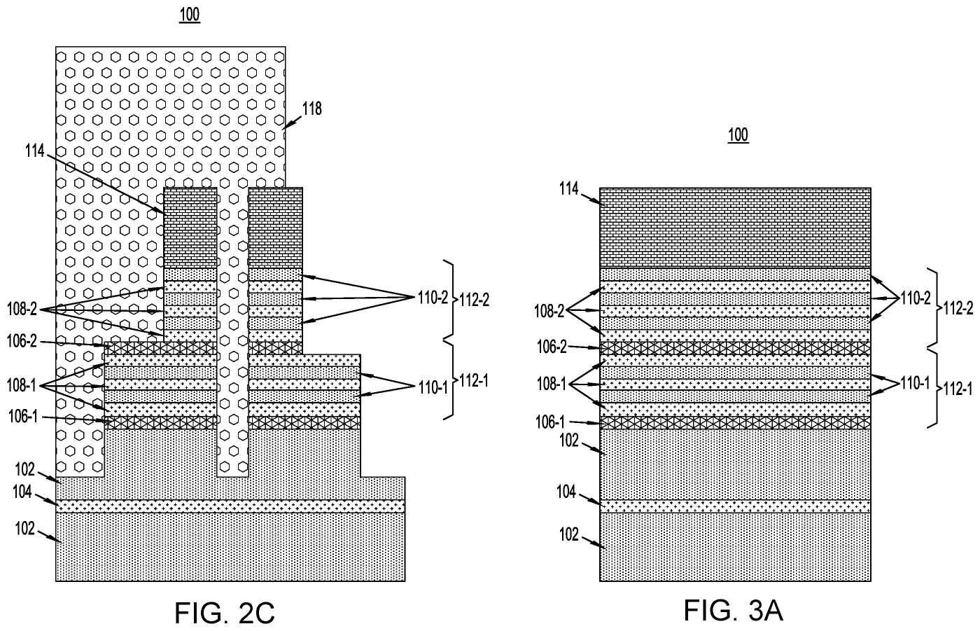

FIGS. 2A-2C illustrate semiconductor structure 100 at a second-intermediate fabrication stage. During this stage, a mask layer 118 (such as an organic planarization layer (OPL) or a spin-on-carbon (SOC)) is deposited on semiconductor structure 100 using any conventional deposition process such spin-on coating or any other suitable deposition process. Next, the mask layer 118 is patterned and then selectively etched using, for example, reactive ion etching (RIE), to remove the exposed portion of sacrificial layer 106-2 of nanosheet stack 116-2.

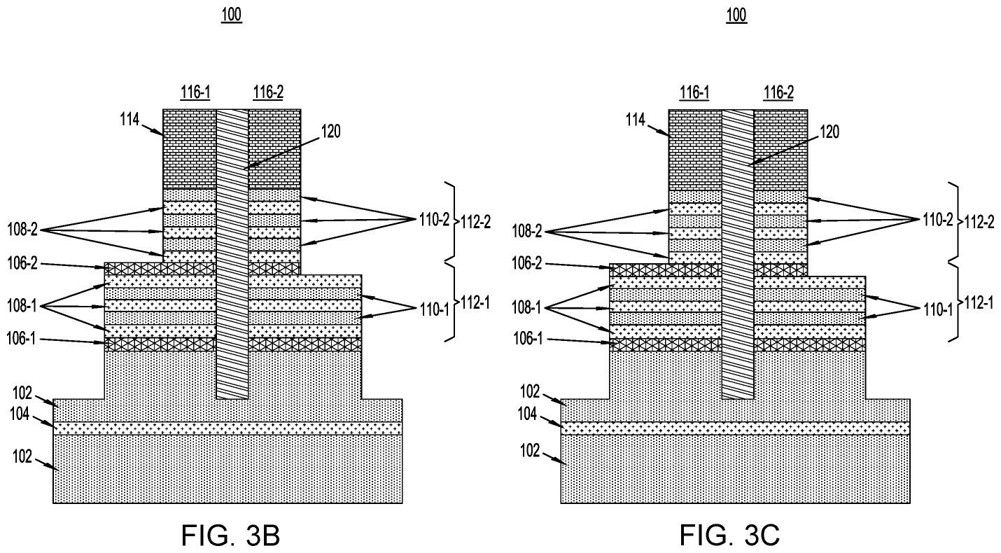

FIGS. 3A-3C show semiconductor structure 100 at a third-intermediate fabrication stage. During this stage, mask layer 118 is removed using any conventional technique such as ashing. Next, isolation dielectric pillar 120 is formed, as shown in FIGS. 3B and 3C, by first depositing a dielectric material over semiconductor structure 100 using any conventional deposition technique such as physical vapor deposition (PVD), atomic layer deposition (ALD), chemical vapor deposition (CVD), etc. An etch back process such as a wet etch is then carried out to remove the dielectric material from semiconductor structure 100 to leave isolation dielectric pillar 120 between nanosheet stacks 116-1 and 116-2. Suitable one or more dielectric materials include, for example, SiN, SiO₂, SiOC, SiOCN, SiBCN, SiC, etc.

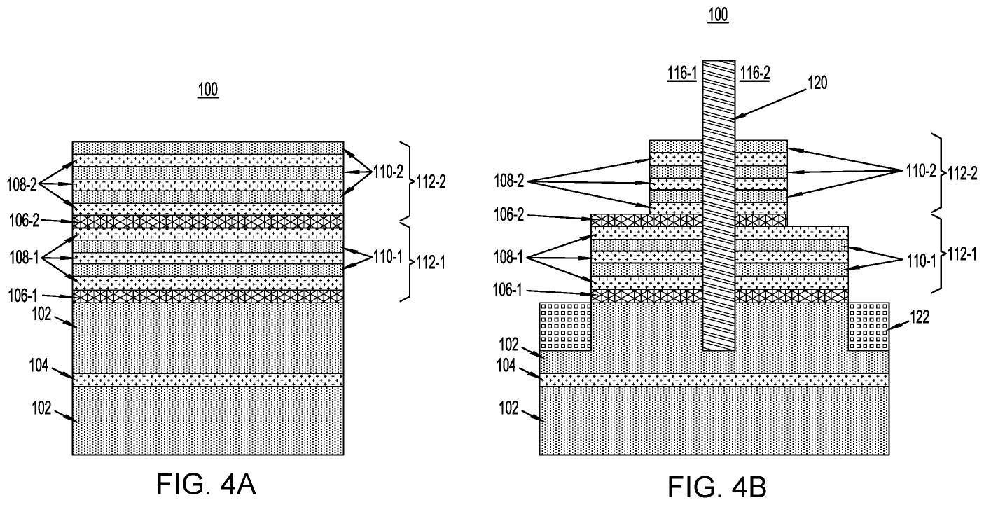

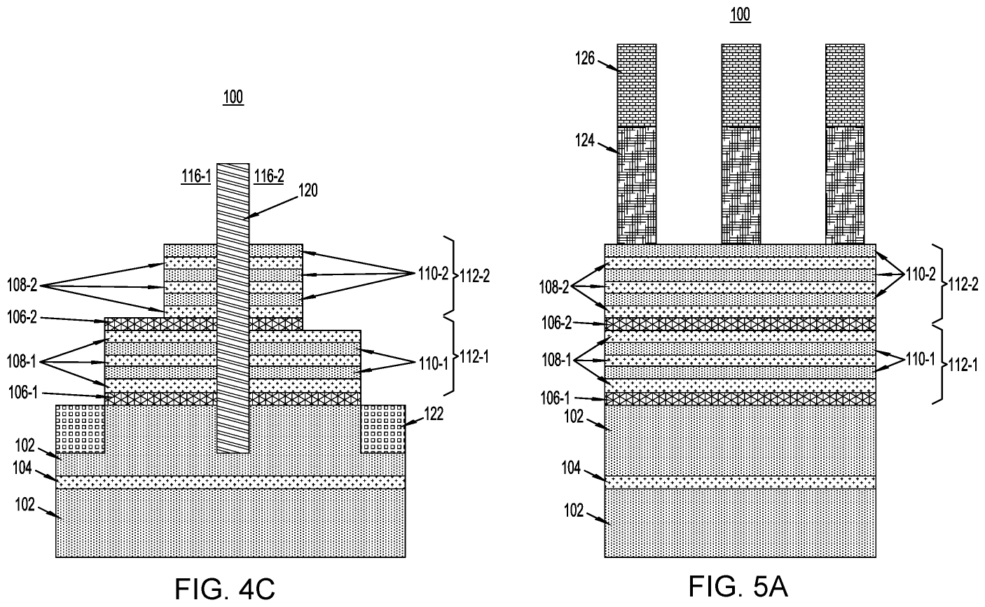

FIGS. 4A-4C illustrate semiconductor structure 100 at a fourth-intermediate fabrication stage. During this stage, a shallow trench isolation (STI) region 122 can be formed on substrate 102. STI region 122 comprises a dielectric material such as silicon oxide or silicon oxynitride, and is formed by methods known in the art. For example, in one illustrative embodiment, STI region 122 is a shallow trench isolation oxide layer. The HM layer 114 can then be removed by any suitable etching technique.

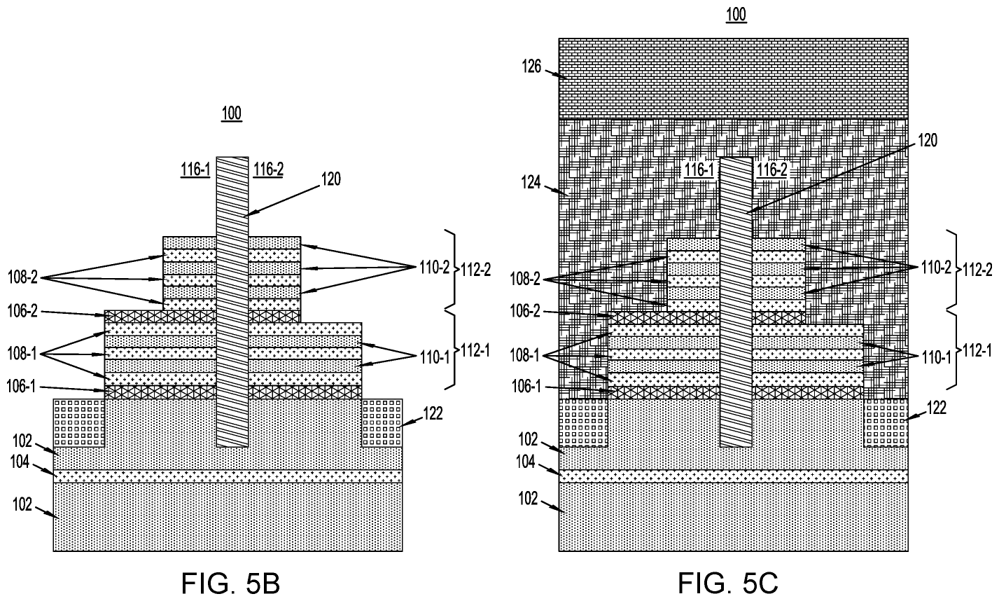

FIGS. 5A-5C illustrate semiconductor structure 100 at a fifth-intermediate fabrication stage. During this stage, dummy gate 124 may be filled over the structure, followed by patterning using a gate hard mask (HM) layer 126. The dummy gate 124 may be formed by blanket deposition of a dummy gate material (e.g., amorphous silicon (a-Si) or amorphous silicon germanium (a-SiGe) over a thin SiO₂ or titanium nitride (TiN) layer, or another suitable material) and material of the gate HM layer 126 (e.g., silicon nitride (SiN), a multi-layer of SiN and SiO₂, or another suitable material), followed by lithographic processing to result in the patterned gate HM layer 126 and underlying dummy gate 124 as shown in FIGS. 5A and 5C.

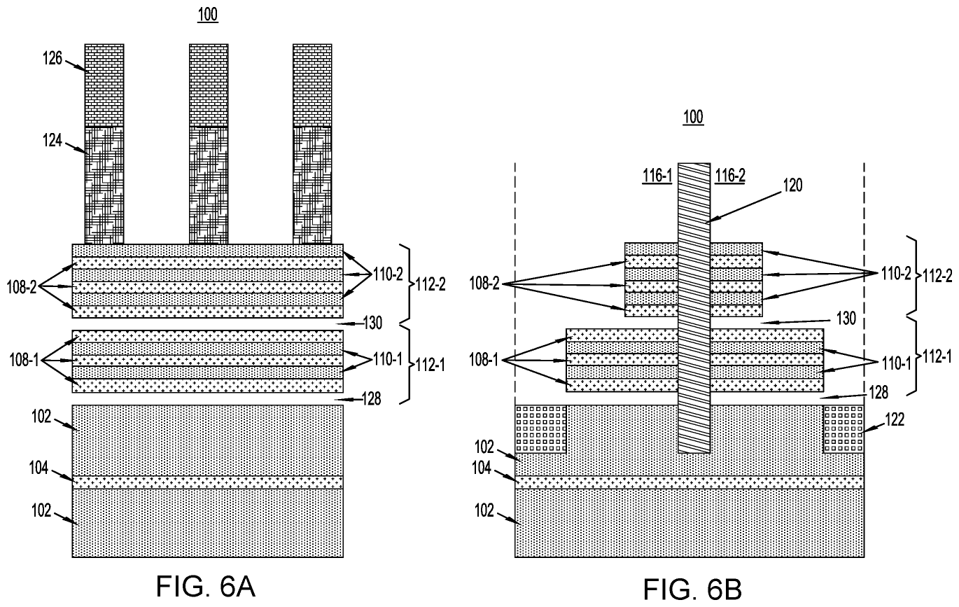

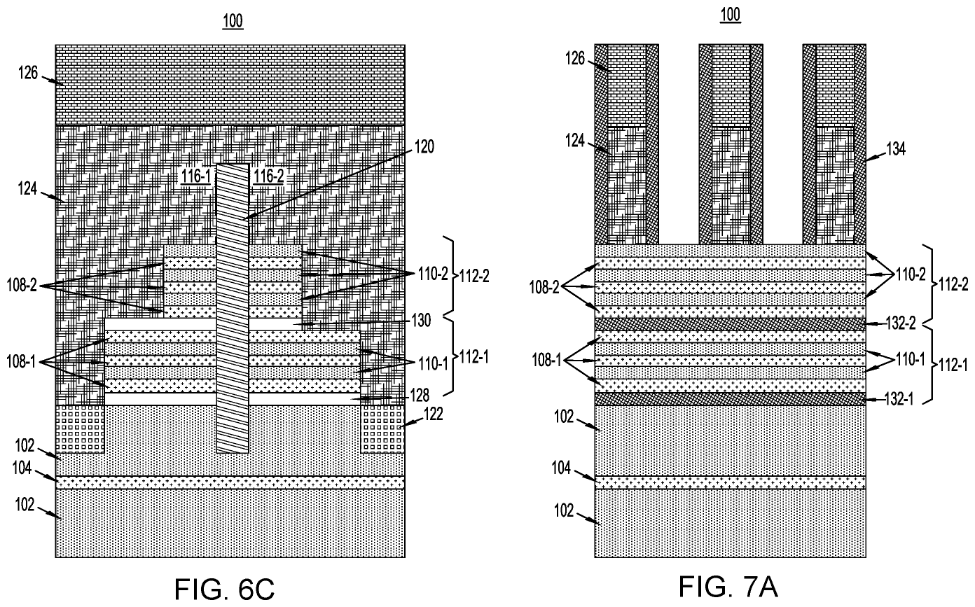

FIGS. 6A-6C illustrate semiconductor structure 100 at a sixth-intermediate fabrication stage. During this stage, sacrificial layers 106 are removed using any suitable selective etch process. For example, sacrificial layer 106-1 can first be removed to form opening 128 and then sacrificial layer 106-2 can be removed to form opening 130.

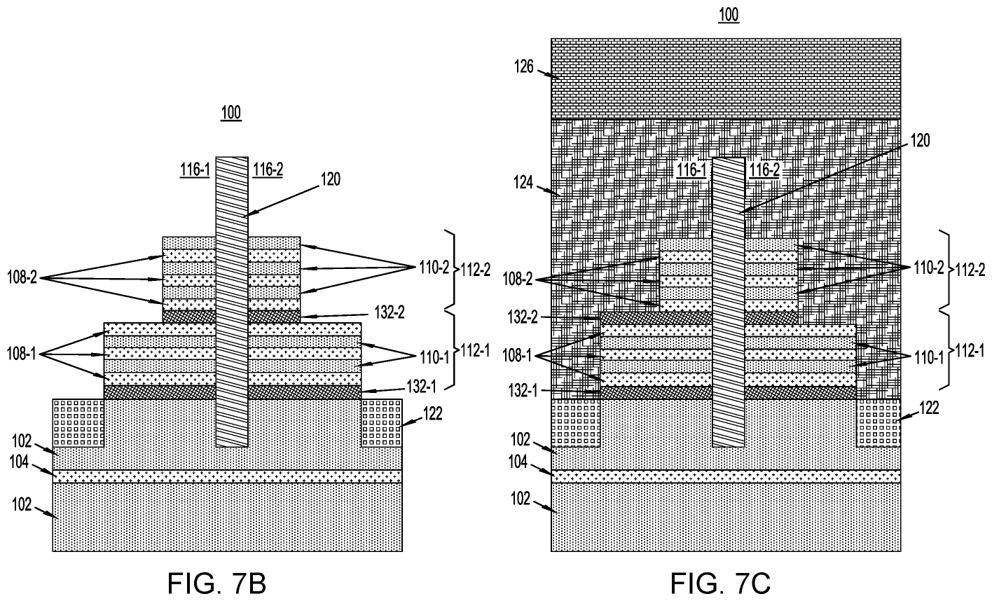

FIGS. 7A-7C illustrate semiconductor structure 100 at a seventh-intermediate fabrication stage. During this stage, a bottom dielectric insulator (BDI) layer 132-1, middle dielectric insulator (MDI) layer 132-2 and sidewall spacers 134 are formed. The BDI layer 132-1 and MDI layer 132-2 (collectively, dielectric insulator layers 132) may be formed of any suitable insulator or dielectric material, such as SiN, silicon boron carbide nitride (SiBCN), silicon oxycarbonitride (SiOCN), etc. The BDI layer 132-1 is formed in the region previously occupied by sacrificial layer 106-1, and the MDI layer 132-2 is formed in the region previously occupied by sacrificial layer 106-2, and may have similar sizing as the sacrificial layers.

In non-limiting illustrative embodiments, MDI layer 132-2 between nanosheet devices 112-1 and 112-2 of nanosheet stack 116-1 is formed of a first width and MDI layer 132-2 between nanosheet devices 112-1 and 112-2 of nanosheet stack 116-2 is formed of a second width less than the first width, as depicted in FIG. 7C. In an illustrative embodiment, the first width of MDI layer 132-2 between nanosheet devices 112-1 and 112-2 of nanosheet stack 116-1 is the same width as the nanosheet channel layers 110-1 of nanosheet device 112-1, and the second width of MDI layer 132-2 between nanosheet devices 112-1 and 112-2 of nanosheet stack 116-2 is the same width as the nanosheet channel layers 110-2 of nanosheet device 112-2.

The sidewall spacers 134 may be formed of materials similar to that of the BDI layer 132-1. In one embodiment, sidewall spacers 134 are formed of the same insulator or dielectric material as BDI layer 132-1 such as SiN or SiBCN.

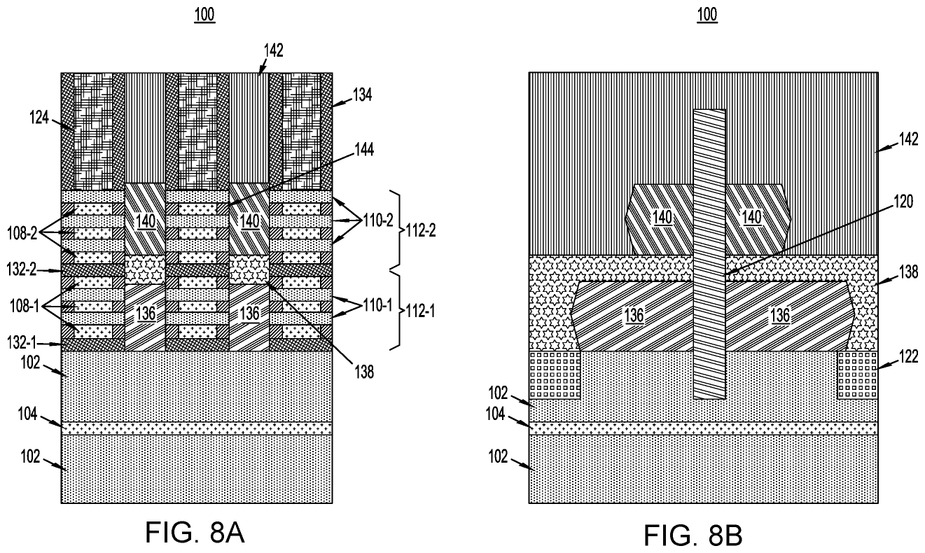

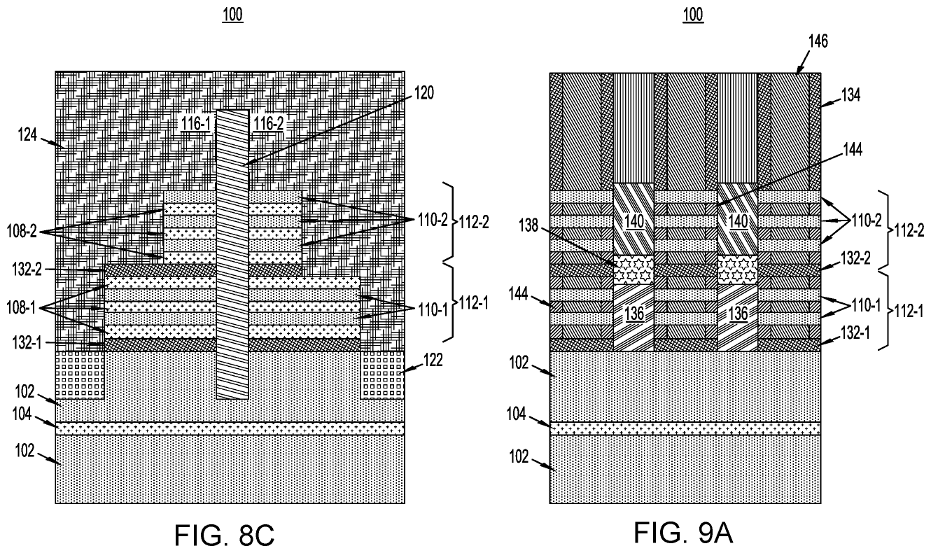

FIGS. 8A-8C show semiconductor structure 100 at an eighth-intermediate fabrication stage. During this stage, bottom source/drain regions 136, bottom interlevel dielectric (ILD) layer 138, top source/drain regions 140, top ILD layer 142 and inner spacers 144 are formed. In illustrative embodiments, bottom source/drain regions 136 are first formed on substrate 102, followed by deposition of bottom ILD layer 138 on bottom source/drain regions 136 and STI region 122, followed by formation of top source/drain regions 140, followed by deposition of top ILD layer 142 on top source/drain regions 140, bottom ILD layer 138 and over isolation dielectric pillar 120, followed by a poly open CMP to reveal the dummy gate 124.

The bottom source/drain regions 136 and the top source/drain regions 140 may be formed using epitaxial growth processes. The bottom source/drain regions 136 and the top source/drain regions 140 may be suitably doped, such as using ion implantation, gas phase doping, plasma doping, plasma immersion ion implantation, cluster doping, infusion doping, liquid phase doping, solid phase doping, etc. N-type dopants may be selected from a group of phosphorus (P), arsenic (As) and antimony (Sb), and p-type dopants may be selected from a group of boron (B), boron fluoride (BF₂), gallium (Ga), indium (In), and thallium (Tl). In some embodiments, the epitaxy process comprises in-situ doping (dopants are incorporated in epitaxy material during epitaxy).

Epitaxial materials may be grown from gaseous or liquid precursors. Epitaxial materials may be grown using vapor-phase epitaxy (VPE), molecular-beam epitaxy (MBE), liquid-phase epitaxy (LPE), rapid thermal chemical vapor deposition (RTCVD), metal organic chemical vapor deposition (MOCVD), ultra-high vacuum chemical vapor deposition (UHVCVD), low-pressure chemical vapor deposition (LPCVD), limited reaction processing CVD (LRPCVD), or other suitable processes. Epitaxial silicon, silicon germanium (SiGe), germanium (Ge), and/or carbon doped silicon (Si:C) can be doped during deposition (in-situ doped) by adding dopants, such as n-type dopants (e.g., phosphorus or arsenic) or p-type dopants (e.g., boron or gallium), depending on the type of transistor to be formed. The dopant concentration in the source/drain region can range from 1×10¹⁹ cm⁻³ to 3×10²¹ cm⁻³, or preferably between 2×10²⁰ cm⁻³ to 3×10²¹ cm⁻³.

The bottom ILD layer 138 and top ILD layer 142 may be independently formed of any suitable isolating material, such as SiO₂, SiOC, SiON, etc.

The inner spacers 144 may be formed to fill indent spaces (e.g., resulting from indent etches of the sacrificial layers 108 prior to their removal). The inner spacers 144 may be formed of silicon nitride (SiN) or another suitable material such as SiBCN, silicon carbide oxide (SiCO), SiOCN, etc.

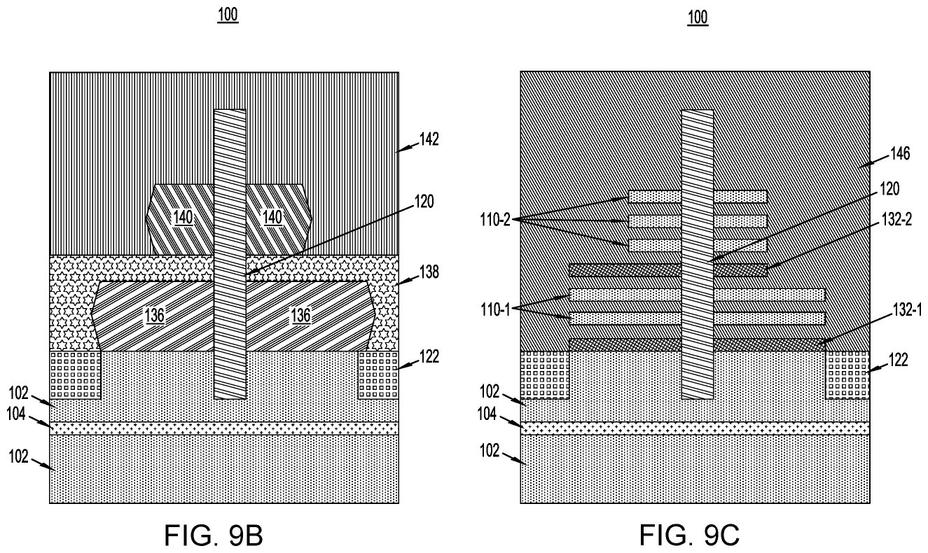

FIGS. 9A-9C show semiconductor structure 100 at a ninth-intermediate fabrication stage. During this stage, dummy gate 124 and sacrificial layers 108 are removed, followed by formation of the replacement gate 146 (e.g., using replacement HKMG processing). The replacement gate 146 includes a gate stack layer which may comprise a gate dielectric layer and a gate conductor layer. The gate dielectric layer may be formed of a high-k dielectric material. Examples of high-k materials include but are not limited to metal oxides such as HfO₂, hafnium silicon oxide (Hf—Si—O), hafnium silicon oxynitride (HfSiON), lanthanum oxide (La₂O₃), lanthanum aluminum oxide (LaAlO₃), zirconium oxide (ZrO₂), zirconium silicon oxide, zirconium silicon oxynitride, tantalum oxide (Ta₂O₅), titanium oxide (TiO₂), barium strontium titanium oxide, barium titanium oxide, strontium titanium oxide, yttrium oxide (Y₂O₃), aluminum oxide (Al₂O₃), lead scandium tantalum oxide, and lead zinc niobate. The high-k material may further include dopants such as lanthanum (La), aluminum (Al), and magnesium (Mg). The gate dielectric layer may have a uniform thickness in the range of 1 nm to 3 nm.

The gate conductor layer may include a metal gate or work function metal (WFM). The WFM for the gate conductor layer may be titanium (Ti), titanium nitride (TiN), tantalum (Ta), tantalum nitride (TaN), aluminum (Al), titanium aluminum (TiAl), titanium aluminum carbon (TiAlC), a combination of Ti and Al alloys, a stack which includes a barrier layer (e.g., of TiN, TaN, etc.) followed by one or more of the aforementioned WFM materials, etc. It should be appreciated that various other materials may be used for the gate conductor layer as desired.

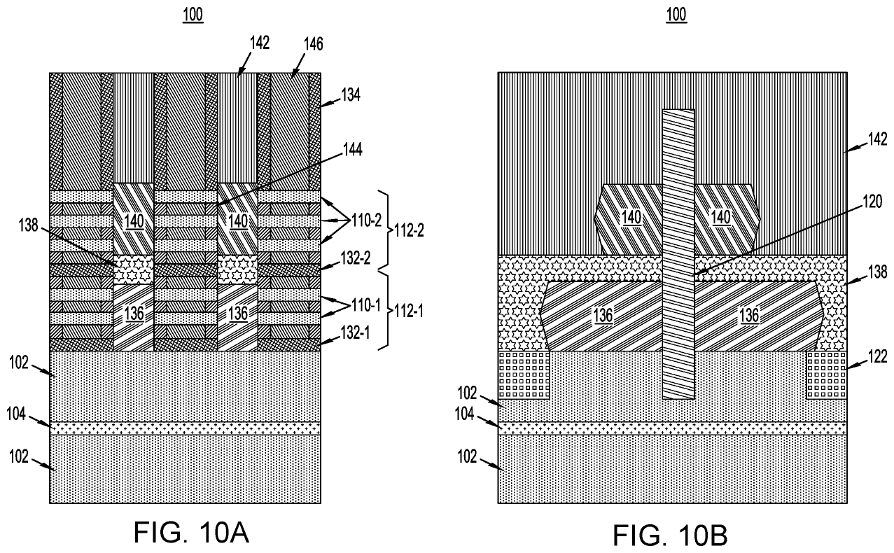

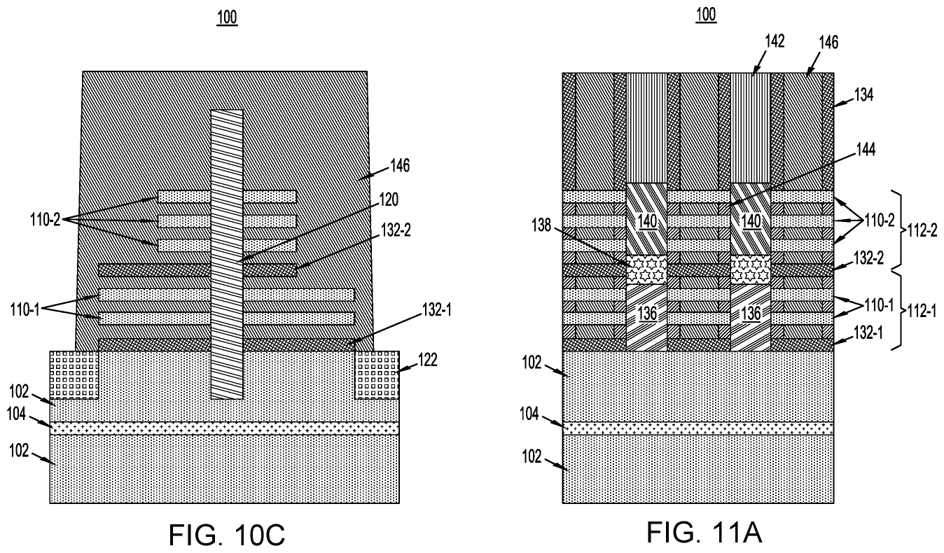

FIGS. 10A-10C illustrate semiconductor structure 100 at a tenth-intermediate fabrication stage. During this stage, a first gate cut is carried out through replacement gate 146 to expose a portion of STI region 122 (see FIG. 10C). The gate cut is carried out using standard lithographic and etching processes such as, for example, RIE.

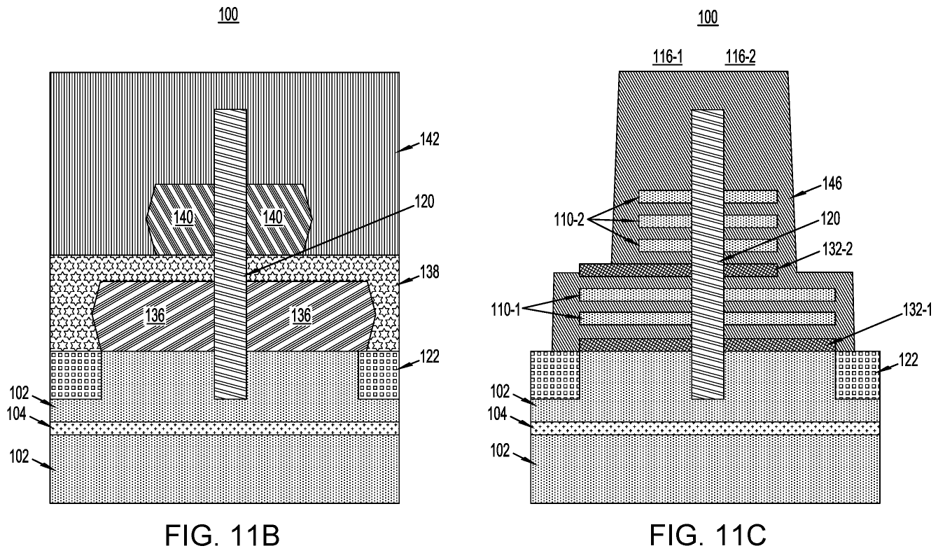

FIGS. 11A-11C illustrate semiconductor structure 100 at an eleventh tenth-intermediate fabrication stage. During this stage, a second gate cut is carried out through replacement gate 146 to expose a portion of MDI layer 132-2 between nanosheet devices 112-1 and 112-2 of nanosheet stack 116-1 and leave MDI layer 132-2 between nanosheet devices 112-1 and 112-2 of nanosheet stack 116-2 within replacement gate 146. (see FIG. 11C). The gate cut is carried out using standard lithographic and etching processes such as, for example, RIE.

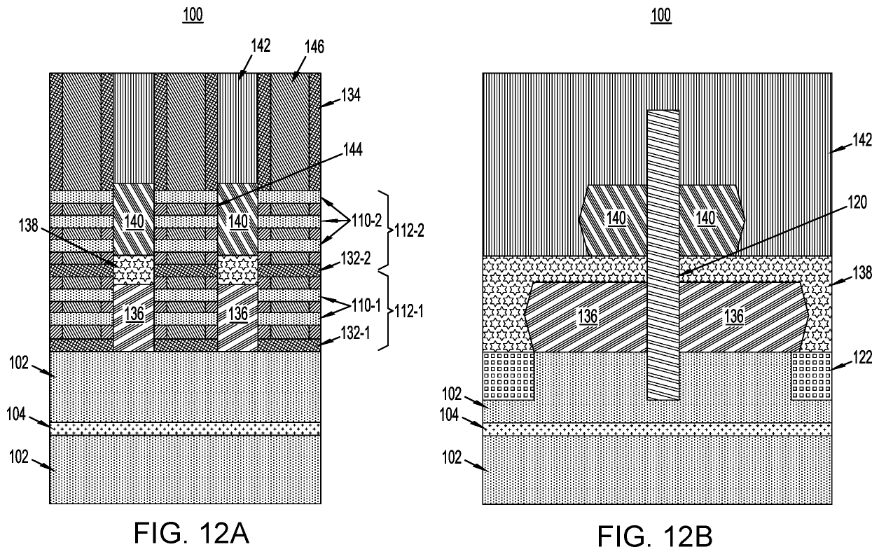

FIGS. 12A-12C illustrate semiconductor structure 100 at a twelfth-intermediate fabrication stage. During this stage, dielectric fill 148 is deposited in the openings, followed by a planarization process such as CMP. Dielectric fill 148 is deposited using any conventional deposition technique such as PVD, ALD, CVD, etc. Suitable dielectric material for dielectric fill 148 includes, for example, SiO₂.

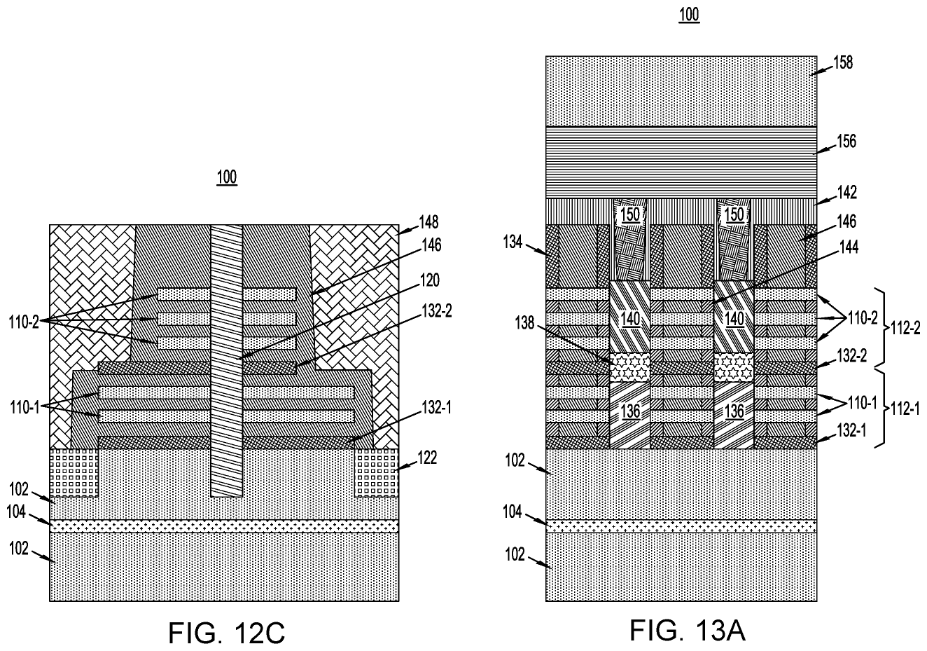

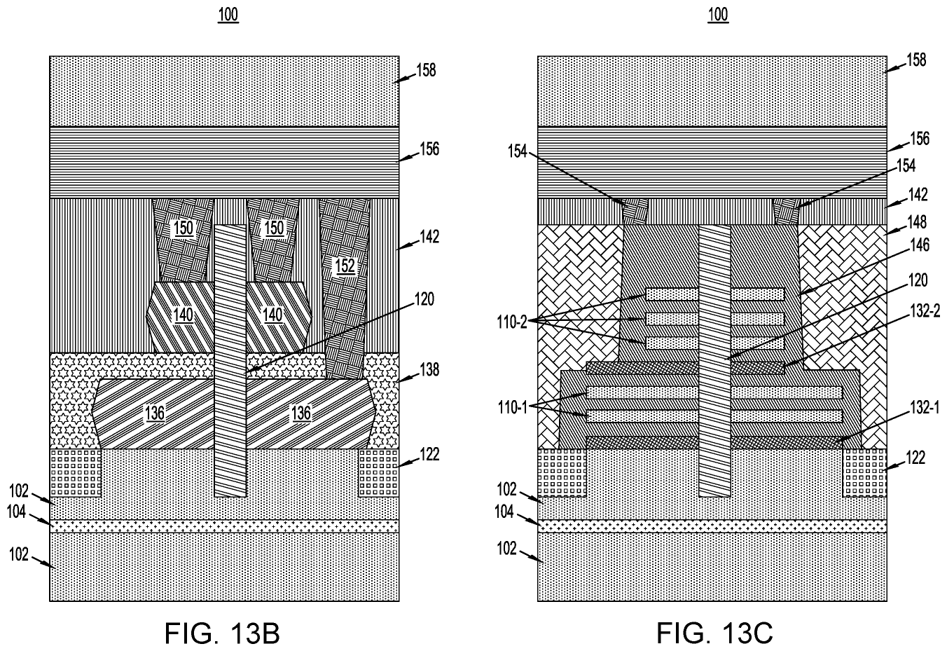

FIGS. 13A-13C illustrate semiconductor structure 100 at a thirteenth-intermediate fabrication stage. During this stage, frontside top source/drain contact contacts 150, frontside bottom source/drain contact 152 and frontside gate contacts 154 are formed. For example, in an illustrative embodiment, top source/drain contact openings and a bottom source/drain contact opening are formed by first depositing a mask layer over semiconductor structure 100, and then utilizing conventional lithographic and etching processes such as RIE in at least one mask layer to form top source/drain contact openings and bottom source/drain contact opening. Next, a high conductance metal is deposited in the top source/drain contact openings and in the bottom source/drain contact opening to form respective frontside top source/drain contacts 150 and frontside bottom source/drain contact 152. Suitable high conductance metal can include, for example, a silicide liner such as Ti, Ni, NiPt, followed by an adhesion metal liner such as TiN, and metal fill material such as tungsten (W), aluminum (Al), copper (Cu), cobalt (Co), ruthenium (Ru), molybdenum (Mo), or any other suitable conductive material. In various embodiments, the high conductance metal can be deposited by ALD, CVD, PVD, and/or plating. The high conductance metal can be planarized using, for example, a planarizing process such as CMP. Other planarization processes can include grinding and polishing.

Frontside gate contacts 154 can be formed utilizing conventional lithographic and etching processes in at least top ILD layer 142, followed by depositing a high conductance metal as discussed above. The high conductance metal can be planarized using, for example, a planarizing process such as CMP. Other planarization processes can include grinding and polishing.

Next, a frontside back-end-of-line (BEOL) structure 156 is formed on semiconductor structure 100 followed by bonding of the structure (e.g., the frontside BEOL structure 156) to a carrier wafer 158. The frontside BEOL structure 156 includes various BEOL interconnect structures. The carrier wafer 158 may be formed of materials similar to that of the substrate 102, and may be formed over the frontside BEOL structure 156 using a wafer bonding process, such as dielectric-to-dielectric bonding.

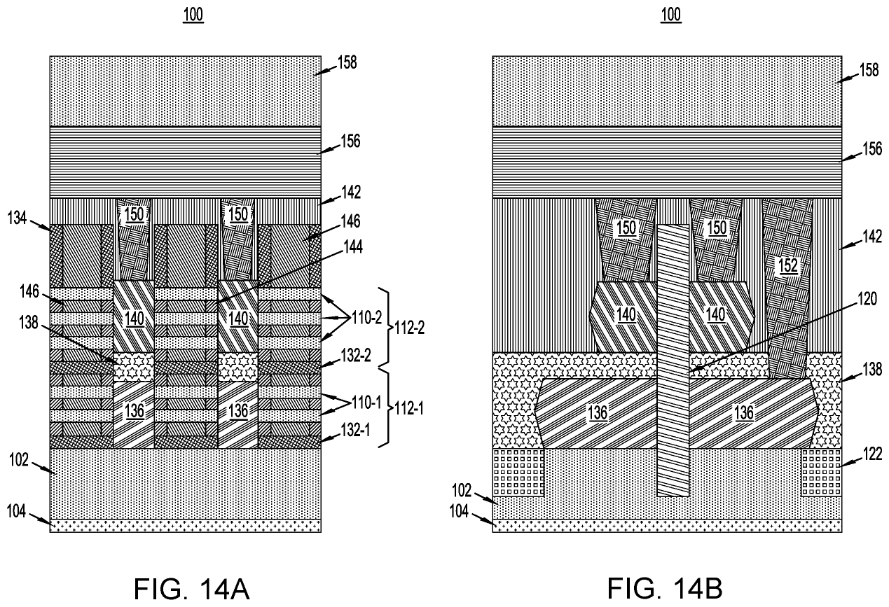

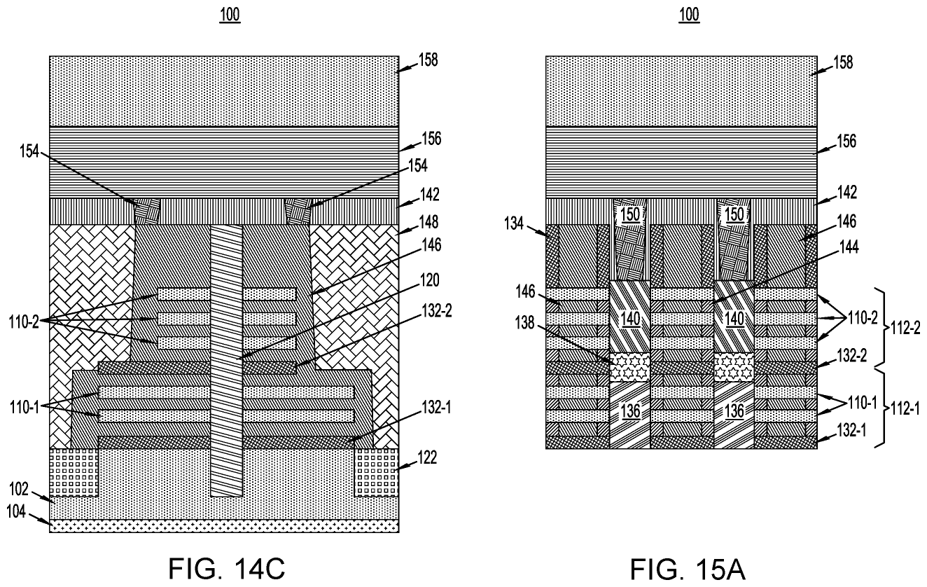

FIGS. 14A-14C illustrate semiconductor structure 100 at a fourteenth-intermediate fabrication stage. During this stage, portions of the substrate 102 may be removed from the backside using, for example, substrate grinding, CMP and a wet etch to selectively remove substrate 102 until the etch stop layer 104 is reached. This can be accomplished, for example, by flipping the semiconductor structure 100 over using the carrier wafer 158 so that the backside of the substrate 102 (i.e., the back surface) is facing up.

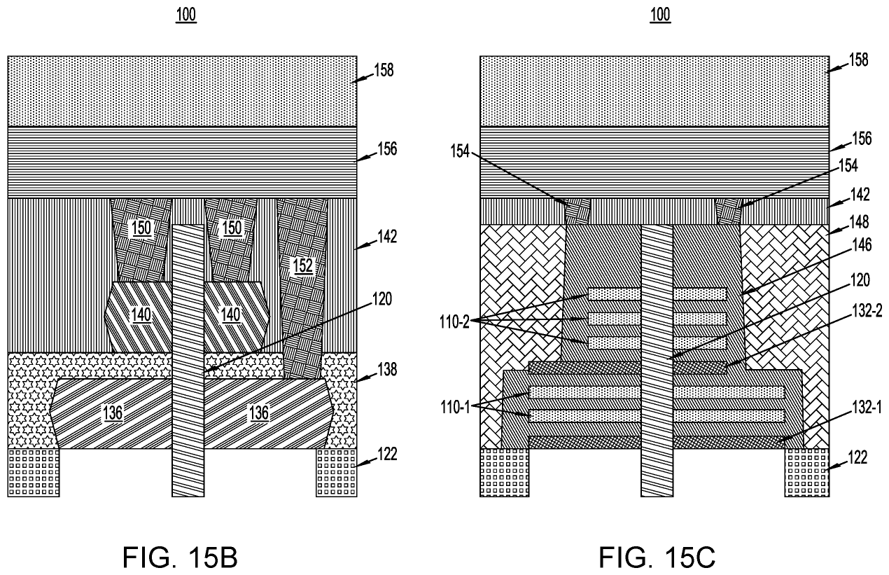

FIGS. 15A-15C illustrate semiconductor structure 100 at a fifteenth-intermediate fabrication stage. During this stage, the etch stop layer 104 is selectively removed using, for example, a wet etch to selectively remove etch stop layer 104 until substrate 102 is reached. Next, the remaining portions of the substrate 102 are removed to expose BDI layer 132-1, isolation dielectric pillar 120, STI region 122 and bottom source/drain regions 136. The remaining portions of the substrate 102 can be removed utilizing a selective etch process such as a wet etch.

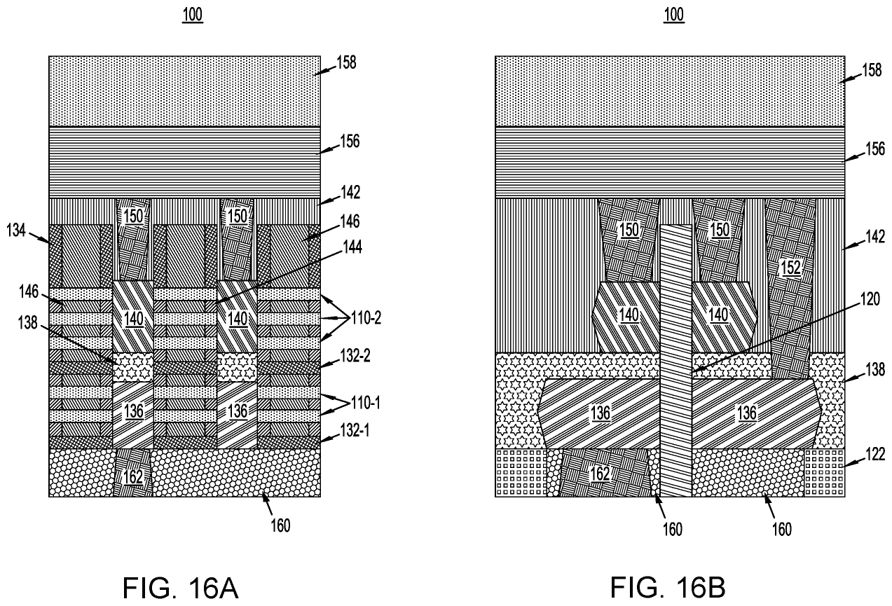

FIGS. 16A-16C illustrate semiconductor structure 100 at a sixteenth-intermediate fabrication stage. During this stage, backside ILD layer 160, backside source/drain contacts 162 and backside gate contact 164 are formed. Backside ILD layer 160 may be formed of similar materials and similar processes as bottom ILD layer 138. The material of the backside ILD layer 160 may initially be overfilled, followed by planarization (e.g., using CMP).

Next, backside source/drain contacts 162 can be formed by, for example, first depositing a mask layer over semiconductor structure 100, and then utilizing conventional lithographic and etching processes such as RIE in at least one mask layer to source/drain contact openings in backside ILD layer 160. Next, a high conductance metal is deposited in the source/drain contact opening to form respective backside source/drain contacts 162. A suitable conductive metal can be any of the metals discussed above. The high conductance metal can be planarized using, for example, a planarizing process such as CMP. Other planarization processes can include grinding and polishing.

Backside gate contact 164 can be formed utilizing conventional lithographic and etching processes in at least backside ILD layer 160, followed by depositing a high conductance metal as discussed above. The high conductance metal can be planarized using, for example, a planarizing process such as CMP. Other planarization processes can include grinding and polishing.

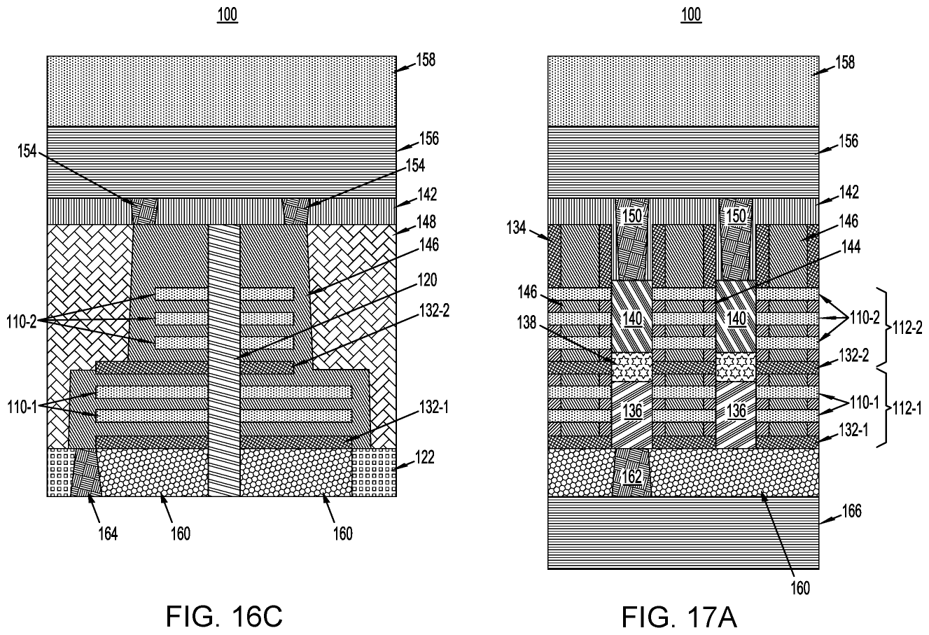

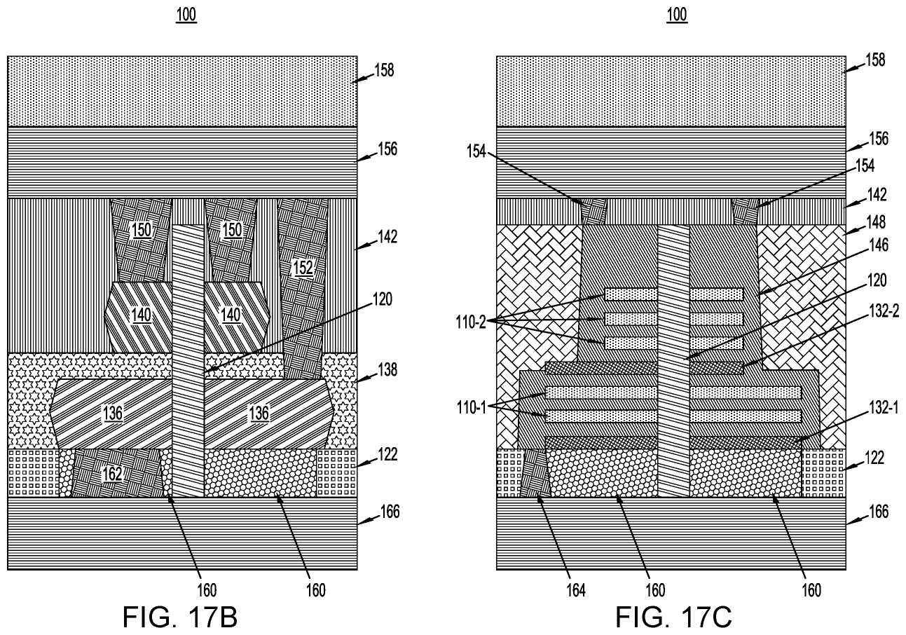

FIGS. 17A-17C illustrate semiconductor structure 100 at a seventeenth-intermediate fabrication stage. During this stage, backside back-end-of-line (BEOL) structure 166 is formed over the semiconductor structure 100 including backside source/drain contacts 162 and backside gate contact 164 and is based on creation of a wiring scheme that is disposed on both sides of the device layer (front end of line structure).

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETs, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a first stacked device comprising:
a first field-effect transistor comprising one or more first nanosheet layers;
a second field-effect transistor vertically stacked above the first field-effect transistor, the second field-effect transistor comprising one or more second nanosheet layers; and
a first dielectric insulator layer positioned between the first field-effect transistor and the second field-effect transistor, the first dielectric insulator layer having a first width; and
a second stacked device adjacent the first stacked device, the second stacked device comprising:
a third field-effect transistor comprising one or more third nanosheet layers;
a fourth field-effect transistor vertically stacked above the third field-effect transistor, the fourth field-effect transistor comprising one or more fourth nanosheet layers; and
a second dielectric insulator layer positioned between the third field-effect transistor and the fourth field-effect transistor, the second dielectric insulator layer having a second width less than the first width of the first dielectric insulator layer.

2. The semiconductor structure according to claim 1, wherein the first width of the first dielectric insulator layer is equal to a third width of the one or more second nanosheet layers, and the second width of the second dielectric insulator layer is equal to a fourth width of the one or more third nanosheet layers.

3. The semiconductor structure according to claim 1, further comprising a third dielectric insulator layer disposed on a bottom surface of the first stacked device and a fourth dielectric insulator layer disposed on a bottom surface of the second stacked device.

4. The semiconductor structure according to claim 1, wherein the first stacked device and the second stacked device are separated by an isolation dielectric pillar.

5. The semiconductor structure according to claim 1, wherein the first field-effect transistor further comprises a first gate structure and the second field-effect transistor further comprise a second gate structure separated from the first gate structure by the first dielectric insulator layer.

6. The semiconductor structure according to claim 5, further comprising a first frontside gate contact connected to the first gate structure and a frontside back-end-of-the-line layer.

7. The semiconductor structure according to claim 6, further comprising a backside gate contact connected to the second gate structure and a backside back-end-of-the-line layer.

8. The semiconductor structure according to claim 1, wherein the second stacked device further comprises a third gate structure disposed over the third field-effect transistor and the fourth field-effect transistor.

9. The semiconductor structure according to claim 8, further comprising a second frontside gate contact connected to the third gate structure and a frontside back-end-of-the-line layer.

10. A semiconductor structure, comprising:
a first stacked device comprising:
a first field-effect transistor comprising a first gate structure;
a second field-effect transistor vertically stacked above the first field-effect transistor, the second field-effect transistor comprising a second gate structure; and
a first dielectric insulator layer positioned between the first field-effect transistor and the second field-effect transistor and separating the first gate structure from the second gate structure; and
a second stacked device adjacent the first stacked device, the second stacked device comprising:
a third field-effect transistor;
a fourth field-effect transistor vertically stacked above the third field-effect transistor;
a second dielectric insulator layer positioned between the third field-effect transistor and the fourth field-effect transistor; and
a third gate structure disposed over the third field-effect transistor, the fourth field-effect transistor and the second dielectric insulator layer.

11. The semiconductor structure according to claim 10, wherein the third gate structure is a shared gate structure between the third field-effect transistor and the fourth field-effect transistor.

12. The semiconductor structure according to claim 11, further comprising a first frontside gate contact connected to the third gate structure and a frontside back-end-of-the-line layer.

13. The semiconductor structure according to claim 12, further comprising a second frontside gate contact connected to the first gate structure and the frontside back-end-of-the-line layer.

14. The semiconductor structure according to claim 13, further comprising a backside gate contact connected to the second gate structure and a backside back-end-of-the-line layer.

15. The semiconductor structure according to claim 10, wherein the first dielectric insulator layer has a first width and the second dielectric insulator layer has a second width less than the first width of the first dielectric insulator layer.

16. The semiconductor structure according to claim 10, wherein the first stacked device and the second stacked device are separated by an isolation dielectric pillar.

17. An integrated circuit, comprising:
one or more semiconductor structures, wherein at least one of the one or more semiconductor structures comprises:
a first stacked device comprising:
a first field-effect transistor comprising a first gate structure;
a second field-effect transistor vertically stacked above the first field-effect transistor, the second field-effect transistor comprising a second gate structure; and
a first dielectric insulator layer positioned between the first field-effect transistor and the second field-effect transistor and separating the first gate structure from the second gate structure; and
a second stacked device adjacent the first stacked device, the second stacked device comprising:
a third field-effect transistor;
a fourth field-effect transistor vertically stacked above the third field-effect transistor;
a second dielectric insulator layer positioned between the third field-effect transistor and the fourth field-effect transistor; and
a third gate structure disposed over the third field-effect transistor, the fourth field-effect transistor and the second dielectric insulator layer.

18. The integrated circuit according to claim 17, wherein the at least one of the one or more semiconductor structures further comprises a first frontside gate contact connected to the third gate structure and a frontside back-end-of-the-line layer.

19. The integrated circuit according to claim 18, wherein the at least one of the one or more semiconductor structures further comprises a second frontside gate contact connected to the first gate structure and the frontside back-end-of-the-line layer, and a backside gate contact connected to the second gate structure and a backside back-end-of-the-line layer.

20. The integrated circuit according to claim 17, wherein the first dielectric insulator layer has a first width and the second dielectric insulator layer has a second width less than the first width of the first dielectric insulator layer.
